(19) United States
(12) Patent Application Publication
(10) Pub. No.: US 2019/0234891 A1
(43) Pub. Date: Aug. 1, 2019

(54) DOWNHOLE DIFFUSION COEFFICIENT MEASUREMENT

(71) Applicant: NMR Services Australia Pty Ltd, Subiaco, Western Australia (AU)

(72) Inventors: Timothy Andrew John HOPPER, Subiao (AU); Matthew SCHUBERT, Rivervale (AU); Benjamin BIRT, Subiaco (AU); Soumyajit MANDAL, Shaker Heights, OH (US)

(73) Assignee: NMR Services Australia Pty Ltd, Subiaco, Western Australia (AU)

(21) Appl. No.: 16/312,179

(22) PCT Filed: Jun. 29, 2017
(86) PCT No.: PCT/AU2017/050674

§ 371 Date: Dec. 20, 2018

(30) Foreign Application Priority Data
Jul. 1, 2016 (AU) 2016902603

(51) Int. Cl. G01N 24/08; G01V 3/32; G01R 33/44; G01V 3/34

(52) U.S. Cl. CPC G01N 24/081; G01V 3/34; G01R 33/448; G01V 3/32

(57) ABSTRACT

A method of determining a multi-dimensional distribution function of fluid types in a sample comprising: (i) applying a sequence of radio frequency pulses to the sample, each pulse having a predetermined phase, the sequence including: a diffusion encoding portion followed by a series of 180-degree refocusing pulses, wherein the diffusion encoding portion comprises repeating blocks of pulses, where the pulses in each block are separated by an interval time of 6, and the blocks themselves by a time delay; (ii) measuring a stimulated echo signal from the sample; (iii) repeating steps (i) to (ii) one or more times with constant 6 to obtain a phase-cycled data set of stimulated echo signal measurements, wherein for each repetition the phase of at least one of the RF pulses is shifted by a predetermined offset; (iv) repeating steps (i) to (iii) one of more times with different 6 values to obtain a series of phase-cycled data sets; and (v) analysing the series of phase-cycled data sets to provide a multi-dimensional distribution function of fluid types within the sample.

This patent application claims priority from Australian Provisional Patent Application No. 2016902603 filed Jul. 01, 2016.

### FIELD OF THE INVENTION

The present invention relates generally to analysis of earth formations and more particularly relates to a borehole nuclear magnetic resonance (NMR) method providing non-invasive in-situ measurement of diffusion coefficients of fluids in earth formations penetrated by a borehole.

### BACKGROUND TO THE INVENTION

The following discussion of the background art is intended to facilitate an understanding of the present invention only. The discussion is not an acknowledgement or admission that any of the material referred to is or was part of the common general knowledge as at the priority date of the application.

Adsorbed gas content in sedimentary earth formations such as coal is typically measured in the laboratory using slow or fast desorption methods on freshly cut core samples. These methods involve sealing the samples in airtight desorption canisters and then measuring the volume of gas that desorbs as a function of time at ambient pressure and temperature. The problem with either method is that overall results can be influenced greatly by artefacts of the test apparatus and procedures used, by core sample type, by sample collection methodology and by the analysis conditions.

For example, in the US Bureau of Mines (USBM) slow desorption method, the measured desorbed gas volume (Q2) is not equal to the total in situ gas content since some gas desorbs and is lost during the sample collection process (Q1) and some of the remainder is usually retained by the coal at ambient conditions (Q3). The sum of Q1, Q2 and Q3 volumes equates to in situ gas content. Even if all these factors are precisely controlled, the accuracy of in situ gas content values obtained using these methods can still be greatly compromised through large errors in Q1 values, which can only be predicted, not measured. Compounding this inherent error of the technique is the fact that core desorption is a destructive testing method that cannot be conducted twice on the same sample. This means it is not possible to assign error bars on core desorption data, or on the major safety implications of decisions made using them.

A further issue with standard Q2 desorption measurements is that it can take many weeks or months to finalise, potentially delaying key decisions on coal mine planning and mining operations. Furthermore, the cores are typically obtained by drilling dedicated coring holes, which are not used for any other purpose. Given the high density of measurements required to establish an accurate lateral map of gas content across a target coal seam, and the large number of cores required for those measurements, desorption testing for gas content requires significant additional drilling and testing costs to properly map gas distribution throughout the resource. Such an approach is often impractical.

Reference to cited material or information contained in the text should not be understood as a concession that the material or information was part of the common general knowledge or was known in Australia or any other country.

Throughout this specification, unless the context requires otherwise, the word “comprise” or variations such as “comprises” or “comprising”, will be understood to imply the inclusion of a stated integer or group of integers but not the exclusion of any other integer or group of integers.

### SUMMARY OF INVENTION

Those skilled in the art will appreciate that the invention described herein is susceptible to variations and modifications other than those specifically described. The invention includes all such variations and modifications. The invention also includes all of the steps, features, formulations, and compounds referred to or indicated in the specification, individually or collectively and any and all combinations or any two or more of the steps or features.

In accordance with the present invention there is provided a method of determining a multi-dimensional distribution function f(T₂, D) of fluid types in a sample, the method comprising the steps of:
(i) applying a sequence of radio frequency (RF) pulses to the sample, each pulse having a predetermined phase, the sequence including: a diffusion encoding portion followed by a series of 180-degree refocusing pulses, wherein the diffusion encoding portion comprises repeating blocks of pulses, where the pulses in each block are separated by an interval time of δ, and the blocks themselves by a time delay (Δ);
(ii) measuring a stimulated echo signal from the sample;
(iii) repeating steps (i) to (ii) one or more times with constant δ to obtain a phase-cycled data set of stimulated echo signal measurements, wherein for each repetition the phase of at least one of the RF pulses is shifted by a predetermined offset;
(iv) repeating steps (i) to (iii) one of more times with different δ values to obtain a series of phase-cycled data sets; and
(v) analysing the series of phase-cycled data sets to provide a multi-dimensional distribution function f(T₂, D) of fluid types within the sample.

Throughout the specification, unless the context requires otherwise, the term “fluid types” will be understood to be used herein to refer to different physical fluid states and properties, including free gas, dissolved gas, adsorbed gas, low viscosity liquid (such as water), medium viscosity liquid (such as medium oil) and high viscosity liquid (such as heavy oil/tar). It is not intended to refer to the different fluid chemistries for the purposes of spectroscopy.

As would be understood by a person skilled in the art, a multi-dimensional distribution function f(T₂, D) is calculated from the phase-cycled data sets using a mathematical inversion. The multi-dimensional distribution function f(T₂, D) may be used to separate out the various fluid types in the sample. Further analysis of the multi-dimensional distribution function f(T₂, D) allows quantitative calculation of the volumetric amount of each fluid type. The inventors have determined that the multi-dimensional distribution function f(T₂, D) produced by the present invention is particularly useful for quantitatively calculating the volume of absorbed gas in the sample.

In one form of the present invention, the sample is selected from the group comprising a rock sample, an earth formation, a subsurface each formation, a portion of an earth formation and a portion of a subsurface earth formation. Preferably, the sample is a portion of subsurface earth formation surrounding a borehole.

In one form of the present invention, the sample is a porous subsurface earth formation containing at least one fluid. Throughout this specification, unless the context requires otherwise, the term “porous” will be understood to is used herein to mean some earth formation containing non-earthen volume or pore space, and includes, but is not limited to consolidated, poorly consolidated, or unconsolidated earthen materials.

In one form of the present invention, the diffusion encoding portion extends for a time, Td. Preferably, Td is between 10 ms and 50 ms. More preferably, T_{d} is between 20 ms and 40 ms. Still preferably, T_{d} is between 25 ms and 35 ms. Still preferably, T_{d} is around 30 ms.

In an alternative form of the present invention, T_{d} is between 10 ms and 45 ms. In an alternative form of the present invention, T_{d} is between 10 ms and 40 ms. In an alternative form of the present invention, T_{d} is between 10 ms and 35 ms. In an alternative form of the present invention, T_{d} is between 10 ms and 30 ms. In an alternative form of the present invention, T_{d} is between 10 ms and 25 ms. In an alternative form of the present invention, T_{d} is between 10 ms and 20 ms. In an alternative form of the present invention, T_{d} is between 10 ms and 15 ms.

In an alternative form of the present invention, T_{d} is between 15 ms and 45 ms. In an alternative form of the present invention, T_{d} is between 15ms and 40 ms. In an alternative form of the present invention, T_{d} is between 15 ms and 35 ms. In an alternative form of the present invention, T_{d} is between 15 ms and 30 ms. In an alternative form of the present invention, T_{d} is between 15 ms and 25 ms. In an alternative form of the present invention, T_{d} is between 15 ms and 20 ms.

In an alternative form of the present invention, T_{d} is between 20 ms and 45 ms. In an alternative form of the present invention, T_{d} is between 20 ms and 40 ms. In an alternative form of the present invention, T_{d} is between 20 ms and 35 ms. In an alternative form of the present invention, T_{d} is between 20 ms and 30 ms. In an alternative form of the present invention, T_{d} is between 20 ms and 25 ms.

In an alternative form of the present invention, T_{d} is between 25 ms and 45 ms. In an alternative form of the present invention, T_{d} is between 25ms and 40 ms. In an alternative form of the present invention, T_{d} is between 25 ms and 35 ms. In an alternative form of the present invention, T_{d} is between 25 ms and 30 ms.

In an alternative form of the present invention, T_{d} is between 30 ms and 45 ms. In an alternative form of the present invention, T_{d} is between 30 ms and 40 ms. In an alternative form of the present invention, T_{d} is between 30 ms and 35 ms.

In an alternative form of the present invention, T_{d} is between 35 ms and 45 ms. In an alternative form of the present invention, T_{d} is between 35ms and 40 ms.

In an alternative form of the present invention, T_{d} is between 40 ms and 45 ms.

In one form of the present invention, the sample is ex situ. In a second form of the present invention, the sample is in situ. Preferably, where the sample is in situ, the sample is a wall of a borehole.

Preferably, an NMR logging tool is used to apply the sequence of RF pulses into the wall of the borehole. More preferably, where the sample is in situ, the NMR logging tool is a downhole NMR logging tool.

As would be understood by those skilled in the art, Nuclear Magnetic Resonance (NMR) logging tools function on the principle that the nuclei of elements such as hydrogen have an angular momentum (“spin”) and a magnetic moment. The nuclear spins will align themselves along an external static magnetic field that is applied by the NMR logging tool. The equilibrium situation can be disturbed by a pulse of an oscillating magnetic field provided by the NMR logging tool. Oscillating magnetic field pulses with 90- and 180- degree tip angles are most common. These pulses tip the spins away from the static field direction. After tipping, two things occur simultaneously. First, the spins precess around the static field at a particular frequency (i.e., the Larmor frequency), given by ω₀=γB₀ where B₀ is the strength of the static field and γ is the gyromagnetic ratio, a nuclear constant. Second, the spins return to the equilibrium direction according to a decay time known as the “spin-lattice relaxation time” or T₁. T₁ is largely controlled by the molecular environment and is typically ten to one thousand milliseconds in rocks.

Also associated with the spin of molecular nuclei is a second relaxation time known as the “spin-spin relaxation time” or T₂. At the end of a ninety degree tipping pulse, all the spins are pointed in a common direction perpendicular, or transverse, to the static field B₀, and they all precess at the Larmor frequency. However, because of small fluctuations in the static field induced by other spins or microscopic material heterogeneities, each nuclear spin precesses at a slightly different rate, i.e., have different Larmor frequencies. Hence, the spins will no longer be precessing in unison. When this dephasing is due to static field inhomogeneity of the apparatus, the dephasing is called T₂*.

As would be understood by a person skilled in the art, NMR diffusion measurements resolve different compounds or ionic species in a mixture based on their differing diffusion coefficients, which depend on the size and shape of the molecules. Following application of an RF pulse with a normal tip angle of 90 degrees, the measured transverse magnetization s(t) is a function of both the diffusion coefficients (D) and the T₂ values of the various molecular components within the sample. These values can be considered to belong to a two-dimensional (2D) multi-dimensional distribution function f(T₂, D). This distribution function is estimated from the measurements by using numerical optimization methods to solve the resulting integral equation.

Those skilled in the art will be aware that there are a number of ways to analyse 2D NMR data. Any number of these methods can be used on the raw data acquired in the specialised pulse sequence detailed above. These 2D inversions of the raw data create the multi-dimensional distribution function f(T₂, D), which can then be used to separate out the various fluids into volumes of each. As discussed above, the inventors have determined that the method of the present invention is particularly useful in determining the volume of absorbed gas. If the process of the present invention is undertaken on a downhole sample, the volume of the downhole adsorbed gas may be converted to cubic meters / tonne of coal based on standard pressure-volume relationships.

For visualisation purposes, the multi-dimensional distribution function f(T₂, D) is plotted as a two dimensional map (T₂-StimD map). Quantitative fluid analysis can be carried out by integrating the portions of the distribution corresponding to various fluid components (water, oil, adsorbed gas), etc. For example, the fractional abundance of a component present within a particular range of T₂ and D values is given by:

aₖ=∫_{T}_{_{2,min}}^{T}^{_{2,max}}∫_{D,min}^{D,max}f(D,T₂)dDdT₂.

Preferably, the series of refocusing pulses comprises a series of 180-degree pulses. Still preferably the series of refocusing pulses comprises a series of composite pulses.

As discussed above, the repeating blocks of pulses are separated by a time delay (Δ). Preferably, Δ is smaller than the longitudinal relaxation time (T₁) associated with the sample. As would be understood by a person skilled in the art, T_{d}=Δ+δ. Preferably, Δ is greater than δ. More preferably, δ is less than Δ/2.

As discussed above, steps (i) and (ii) are repeated one or more times with different phase offsets to obtain the phase-cycled data set. It will be understood that each repetition has a distinct set of phase offsets to the preceding sets. Each repetition therefore provides a distinct part of the phase-cycled data set. Preferably, steps (i) and (ii) are repeated 2 or more times with different phase offsets to obtain the phase-cycled data set. More preferably, steps (i) and (ii) are repeated 3 or more times with different phase offsets to obtain the phase-cycled data set. Still preferably, steps (i) and (ii) are repeated 4 or more times with different phase offsets to obtain the phase-cycled data set. Still preferably, steps (i) and (ii) are repeated 5 or more times with different phase offsets to obtain the phase-cycled data set. Still preferably, steps (i) and (ii) are repeated 6 or more times with different phase offsets to obtain the phase-cycled data set. Still preferably, steps (i) and (ii) are repeated 7 or more times with different phase offsets to obtain the phase-cycled data set. Still preferably, steps (i) and (ii) are repeated 8 or more times with different phase offsets to obtain the phase-cycled data set. Still preferably, steps (i) and (ii) are repeated 9 or more times with different phase offsets to obtain the phase-cycled data set. Still preferably, steps (i) and (ii) are repeated 10 or more times with different phase offsets to obtain the phase-cycled data set. Still preferably, steps (i) and (ii) are repeated 11 or more times with different phase offsets to obtain the phase-cycled data set. Still preferably, steps (i) and (ii) are repeated 12 or more times with different phase offsets to obtain the phase-cycled data set. Still preferably, steps (i) and (ii) are repeated 13 or more times with different phase offsets to obtain the phase-cycled data set. Still preferably, steps (i) and (ii) are repeated 14 or more times with different phase offsets to obtain the phase-cycled data set. Still preferably, steps (i) and (ii) are repeated 15 or more times with different phase offsets to obtain the phase-cycled data set.

In a preferred form of the present invention steps (i) to (ii) are repeated through each part of a 16-part phase cycle comprising 16 phase distinct sequences of radio frequency (RF) pulses.

In one form of the present invention, the 16-part phase cycle is repeated one or more times for the same δ value to provide averaged results.

The inventors have determined that by obtaining a series of phase-cycled data sets for different δ intervals, a quantitative analysis of the amount of adsorbed gas in the borehole can be determined. In one form of the present invention, step (iii) is repeated two or more times for different δ values. Preferably, step (iii) is repeated three or more times for different δ values. More preferably, step (iii) is repeated four or more times for different δ values. More preferably, step (iii) is repeated five or more times for different δ values. More preferably, step (iii) is repeated six or more times for different δ values. More preferably, step (iii) is repeated seven or more times for different δ values. More preferably, step (iii) is repeated eight or more times for different δ values. More preferably, step (iii) is repeated nine or more times for different δ values. More preferably, step (iii) is repeated ten or more times for different δ values. More preferably, step (iii) is repeated eleven or more times for different δ values.

Preferably, the value of δ is between 0 ms and 30 ms. More preferably, the value of δ is between 0 ms and 25 ms. Still preferably, the value of δ is between 0 ms and 20 ms. Still preferably, the value of δ is between 0 ms and 15 ms.

In an alternative form of the present invention, the value of δ is between 5 ms and 30 ms. In an alternative form of the present invention, the value of δ is between 5 ms and 25 ms. In an alternative form of the present invention, the value of δ is between 5 ms and 20 ms. In an alternative form of the present invention, the value of δ is between 5 ms and 25 ms. In an alternative form of the present invention, the value of δ is between 5 ms and 20 ms. In an alternative form of the present invention, the value of δ is between 5 ms and 15 ms. In an alternative form of the present invention, the value of δ is between 5 ms and 10 ms.

In an alternative form of the present invention, the value of δ is between 10 ms and 30 ms. In an alternative form of the present invention, the value of δ is between 10 ms and 25 ms. In an alternative form of the present invention, the value of δ is between 10 ms and 20 ms. In an alternative form of the present invention, the value of δ is between 10 ms and 25 ms. In an alternative form of the present invention, the value of δ is between 10 ms and 20 ms. In an alternative form of the present invention, the value of δ is between 10 ms and 15 ms.

In an alternative form of the present invention, the value of δ is between 15 ms and 30 ms. In an alternative form of the present invention, the value of δ is between 15 ms and 25 ms. In an alternative form of the present invention, the value of δ is between 15 ms and 20 ms.

In an alternative form of the present invention, the value of δ is between 20 ms and 30 ms. In an alternative form of the present invention, the value of δ is between 20 ms and 25 ms.

In an alternative form of the present invention, the value of δ is between 25 ms and 30 ms.

In one form of the present invention, the multi-dimensional distribution function f(T₂, D) of the sample is used to differentiate different types and physical states of fluids, or fluid components in the sample. Preferably, the multi-dimensional distribution function f(T₂, D) of the sample is used to determine the volume of fluids in the sample. In one form of the present invention, the multi-dimensional distribution function f(T₂, D) of the sample is used to determine the volume of absorbed gases in the sample. Preferably, the volume of adsorbed gas in sample is calculated as a function of m³/tonne of coal.

In accordance with a further aspect of the present invention, there is provided a method of measuring the volume of absorbed gas in a subsurface earth formation, the method comprising the steps of:
i. providing a multi-dimensional distribution function f(T₂, D) of fluids within the subsurface earth formation using the above described method; and
ii. using the multi-dimensional distribution function f(T₂, D) to determine the volume of absorbed gases in the subsurface earth formation.

In one form of the present invention, the subsurface earth formation comprises coal. Preferably, the volume of adsorbed gas in the coal is calculated as a function of m³/tonne of coal.

### BRIEF DESCRIPTION OF THE DRAWINGS

Further features of the present invention are more fully described in the following description of several non-limiting embodiments thereof. This description is included solely for the purposes of exemplifying the present invention. It should not be understood as a restriction on the broad summary, disclosure or description of the invention as set out above. The description will be made with reference to the accompanying drawings in which:

FIG. 1 is a schematic representation of a RF pulse sequence that may be used in accordance with the invention;

FIG. 2 shows the estimated diffusion contrast, signal-to-noise ratio (SNR), and measurement sensitivity as a function of D and T₂;

FIG. 3 shows the effect that a greater T₁/T₂ ratio has on the estimated diffusion contrast, SNR, and measurement sensitivity as a function of D and T₂;

FIG. 4 shows the effect that a greater T_{d} has on the estimated diffusion contrast, SNR, and measurement sensitivity as a function of D and T₂;

FIG. 5 shows a two dimensional T₂-StimD map generated for Example 1; and

FIG. 6 shows a two dimensional T₂-StimD map generated for Example 1 which has been annotated to indicate the expected areas of signals for different fluid components.

FIG. 7 shows a routine that may be used in implementing one embodiment of a method of the invention

FIG. 8 shows a routine that may be used to computed adsorbed gas content in coal using computed volumes of water and adsorbed gas from NMR measurements

### DETAILED DESCRIPTION OF THE DISCLOSURE

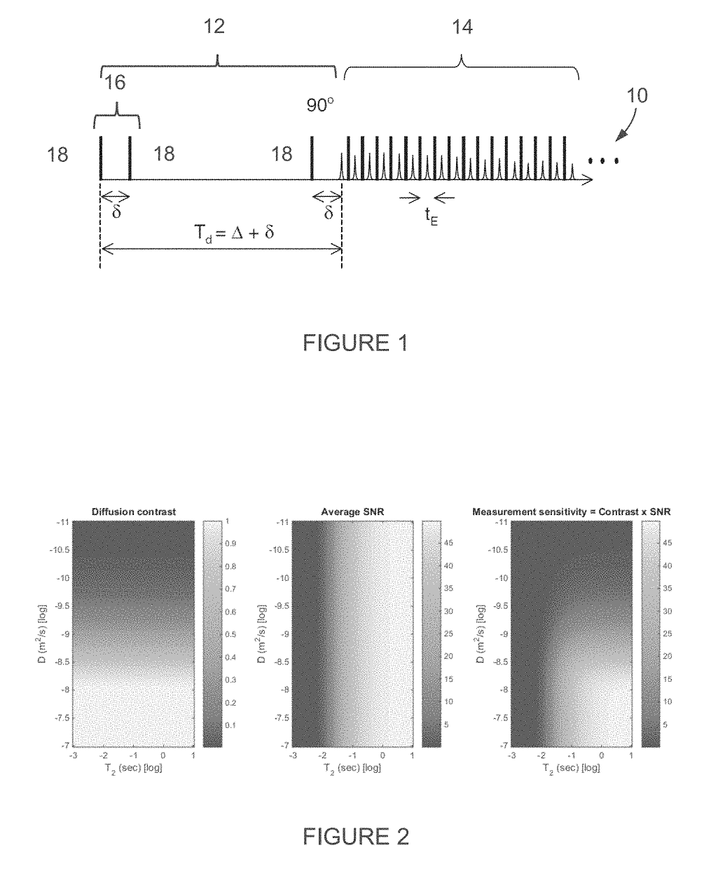

The present invention relates to a method of determining the multi-dimensional distribution function f(T₂, D) of fluids occupying the pore structure in a rock sample, for example the wall of a borehole, the method generally relating to using a borehole NMR device for applying a sequence of RF pulses 10 to a system of nuclear spins, such as a fluid in a rock wall of the borehole, detecting a series of magnetic resonance signals (also known as spin echoes) from the rock wall of the borehole and analysing the series of magnetic resonance signals to provide diffusion constants. As best seen in FIG. 1, the sequence of RF pulses 10 comprises two parts, a diffusion encoding portion 12 and a series of refocusing pulses 14.

The diffusion encoding portion 12, which extends for a time T_{d}, is designed to prepare the system of nuclear spins in an initial state that is dependent on the diffusion coefficient. The series of refocusing pulses 14 then generates from the system of spins a series of magnetic resonance signals that depends on T₂.

Following the diffusion encoding portion 12, the series of refocusing pulses 14 is applied. The series of nominally 180-degree RF refocusing pulses 14 forms part of a Carr-Purcell-Meiboom-Gill (CPMG) sequence, which may be used for measuring T₂. It generates a series of spin echoes whose time-varying magnetization can be recorded using an inductor (coil) and the principle of Faraday induction. A number of such series are measured for different values of δ and then combined to extract a two-dimensional relaxation-diffusion multi-dimensional distribution function f(T₂, D).

As the NMR excitation and resulting spin echo measurements occur downhole in a grossly inhomogeneous static magnetic field, the inventors have determined that the sequence of RF pulses 10 need to be repeatedly applied to the fluid in rock wall of the borehole to increase the signal-to-noise ratio (SNR). In order to select a particular coherence pathway (the so-called stimulated echo) during the diffusion encoding period 12 and also reduce the effects of pulse ringdown on the measured signals, the phase of at least one of the RF pulses is shifted by a predetermined offset. The sequence may then be repeated a number of times with a different phase shift applied to at least one of the RF pulses to build a phase cycled data set for a particular δ value. As would be understood by a person skilled in the art, phase cycling may be performed by varying the phase of magnetic field pulses within a given sequence or by varying the phase of magnetic field pulses from sequence to sequence. In a preffered form of the present invention, a 16-part phase cycle may be implented as shown in Table 1:

TABLE 1
16-part phase cycle

| φ1 | φ2 | φ3 | φ180 | φacq |
|---|---|---|---|---|
| 0 | 0 | 0 | π/2 | π |
| π | 0 | 0 | π/2 | 0 |
| 0 | π | 0 | π/2 | 0 |
| π | π | 0 | π/2 | π |
| 0 | 0 | π | π/2 | 0 |
| π | 0 | π | π/2 | π |
| 0 | π | π | π/2 | π |
| π | π | π | π/2 | 0 |
| π/2 | 0 | 0 | 0 | π/2 |
| −π/2 | 0 | 0 | 0 | −π/2 |
| π/2 | π | 0 | 0 | −π/2 |
| −π/2 | π | 0 | 0 | π/2 |
| π/2 | 0 | π | 0 | −π/2 |
| −π/2 | 0 | π | 0 | π/2 |
| π/2 | π | π | 0 | π/2 |
| −π/2 | π | π | 0 | −π/2 |

The first three columns in Table 1 represent the phases of the three nominally 90-degree pulses during the diffusion encoding period 12. The fourth column represents the phases of the nominally 180-degree refocusing pulses 14, and the fifth column represents the phase with which the measured signals (spin echoes) are acquired and processed. All phases are expressed in radians and measured in the rotating frame, i.e., with respect to a stable reference oscillator running at the RF frequency. During each of these cycles δ is kept constant.

Phase-cycled data sets are then collected for several values of δ in order to obtain a series of phase-cycled data sets. The inventors have discovered that by providing at least two phase-cycled data sets, sufficient data to differentiate between adsorbed gases, oils, and water within the sample can be achieved.

Preferably, for each phase-cycled data set, the value of Δ should be adjusted in order to keep δ+Δ constant across all phase-cycled data sets. As would be understood by a person skilled in the art, the maximum value of δ is Δ, but in practice it is usually limited to Δ/2 or less in order to minimize the amount of transverse (T₂) relaxation during the diffusion encoding period. In addition, the spacing of the two initial 90-degree pulses should be reduced to Δ=δ−2t₉₀/TT where t₉₀ is the length of each of these pulses to compensate for finite pulse width effects.

After the end of the initial diffusion encoding portion, the measured echo amplitudes as a function of echo number (k) and δ are given by

A(kt_{E},δ)=∫∫∫dDdT_{2eff}dT₁f(D,T_{2eff},T₁)e^{T}^{_{d}}^{/T}^{₁}e^{-2δ(1/T}^{₂}^{-1/T}^{₁}⁾^{-q}^{²}^{D(Δ-δ/B)}e^{-kt}^{_{E}}^{/T}^{_{2eff}}.

Here q≡γgδ where γ is the gyromagnetic ratio of the nucleus and g is the static field gradient. In addition, f(T₁,T_{23eff},D) is the three-dimensional (3D) relaxation-diffusion multi-dimensional distribution function of the sample. However, it is difficult to invert this 3D integral equation to find f(T₁,T_{2eff},D). Instead, the two-dimensional (2D) diffusion-relaxation distribution function of spins that survive for time T_{d} are defined as:

f_{T}_{_{d}}(D,T_{2eff})=∫dT₁f(D,T_{2eff},T₁)e^{-T}^{_{d}}^{/T}^{₁}.

If we further assume that δ<<T_{d}, the e^{-2δ(1/T}^{₂}^{-1/T}^{₁}⁾ term is negligible compared to e^{-T}^{_{d}}^{/T}^{₂}. The measured echo amplitudes are then given by

A(kt_{E},δ)=∫∫dDdT_{2eff}f_{T}_{_{d}}(D,T_{2eff})e^{a}^{²}^{D(T}^{_{d}}^{4δ/3)}e^{-kt}^{_{E}}^{T}_{2eff}.

This 2D integral equation can be solved to find f_{T}_{_{d}}(D,T_{2eff}) by using numerical optimization; specifically, regularized 2D inverse Laplace transform (ILT) methods that are well known in the art. Note that F_{T}_{_{d}}(T_{2eff},D) has also been referred to as f(T₂, D) for simplicity in notation.

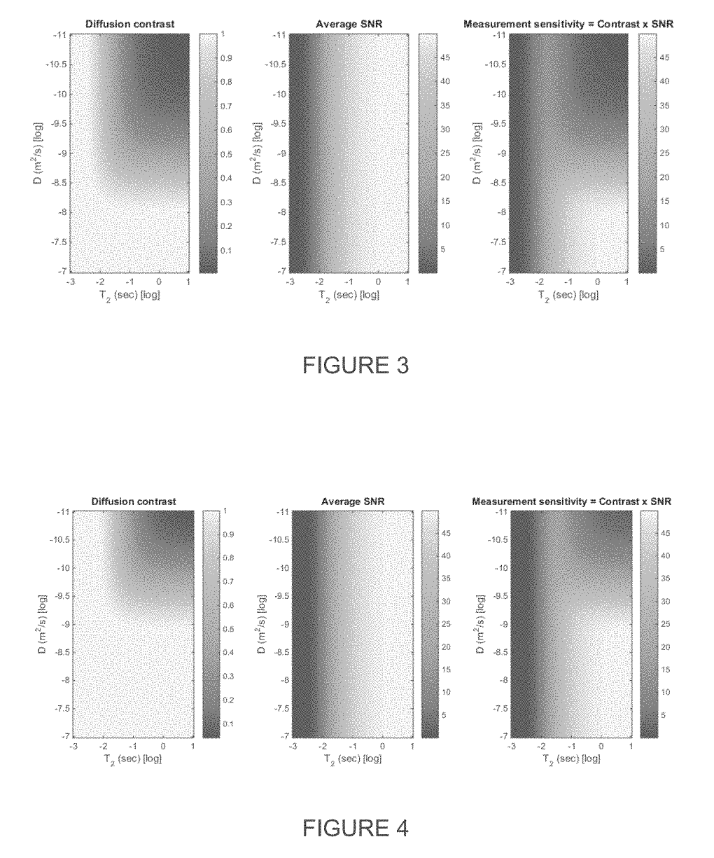

The inventors have determined that the sensitivity of the diffusion encoding pulse sequence is affected by two quantities: diffusion contrast (defined as the ratio of change in initial signal amplitude to the maximum amplitude as a function of δ) and signal-to-noise ratio or SNR (defined as the sum of the echo amplitudes relative to the measurement noise floor). Specifically, the product of these two quantities can be used as an approximate measure of sensitivity. In order to optimise the parameters of the diffusion encoding pulse sequence, a series of experiments were conducted to determine the effect that individual parameters had on the estimated diffusion contrast, SNR and measurement sensitivity. For the purposes of these experiments, the following values were assumed: g=0.1 T/m (10 G/cm) and t_{E}=200 μs. These values are typical of the NMRSA borehole NMR device, referred to as the BMR logging tool. FIG. 2 shows the estimated diffusion contrast, SNR, and measurement sensitivity as a function of D and T₂ while assuming a fixed T₁/T₂ ratio of 1. FIG. 3 shows the estimated diffusion contrast, SNR, and measurement sensitivity as a function of D and T₂ while assuming a fixed T₁/T₂ ratio of 5. Sensitivity to lower values of D can be improved by increasing T_{d}. However, this is accompanied by reduced sensitivity to lower values of T₂. FIG. 4 shows the effect of increasing T_{d}. These results show the expected behaviour: measurement sensitivity is highest when both D and T₂ are large, and lowest when they are both small.

In order to measure adsorbed gas content within a sample, diffusion constants of around D=10⁻¹⁰ m²/s are preferably able to be differentiated. The inventors have determined that in order to measure diffusion constants of around D=10⁻¹⁰ m²/s with the NMRSA BMR logging tool for example, it is preferable to use Td≈30 ms with 11 uniformly spaced values of δ between 0 and 15 ms. The final SNR can then be improved if necessary either by increasing the number of scans for each value of δ (in steps of 16), or by increasing the number of δ values within the specified range (15 ms). Both approaches are roughly equivalent in terms of total experimental time.

During use, a BMR logging tool (not shown) is inserted into the borehole and a sequence of RF pulses is applied to the fluid in the rock around the borehole and the spin echo signals are received and analysed. This is repeated in a 16-part phase cycle across a number of different δ values.

### EXAMPLE 1

The present invention is not to be limited in scope by any of the specific embodiments described herein. These embodiments are intended for the purpose of exemplification only. Functionally equivalent products, formulations and methods are clearly within the scope of the invention as described herein.

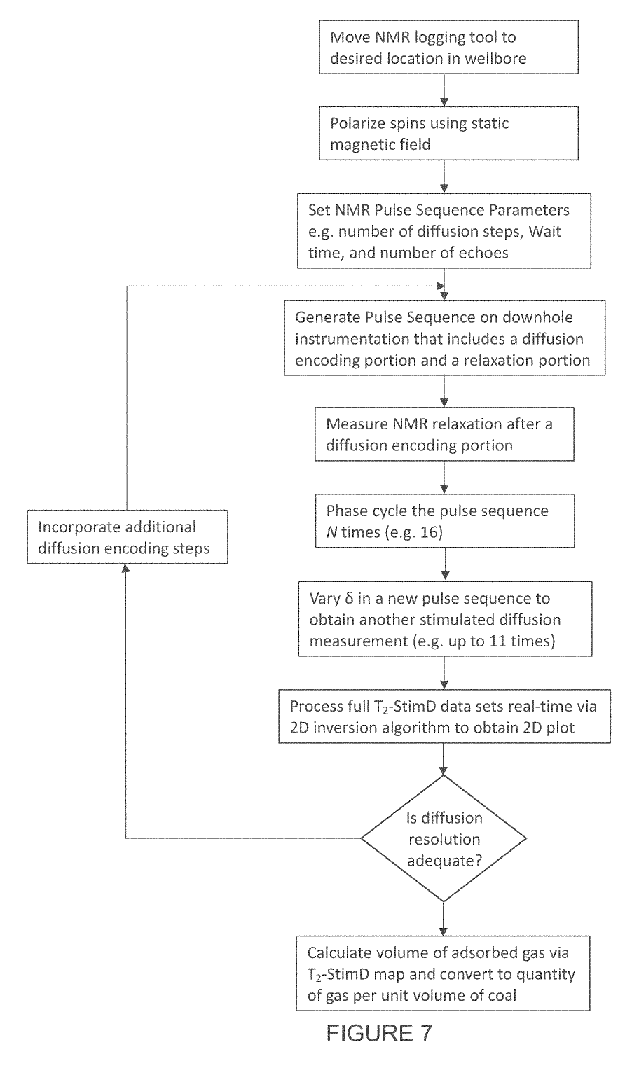

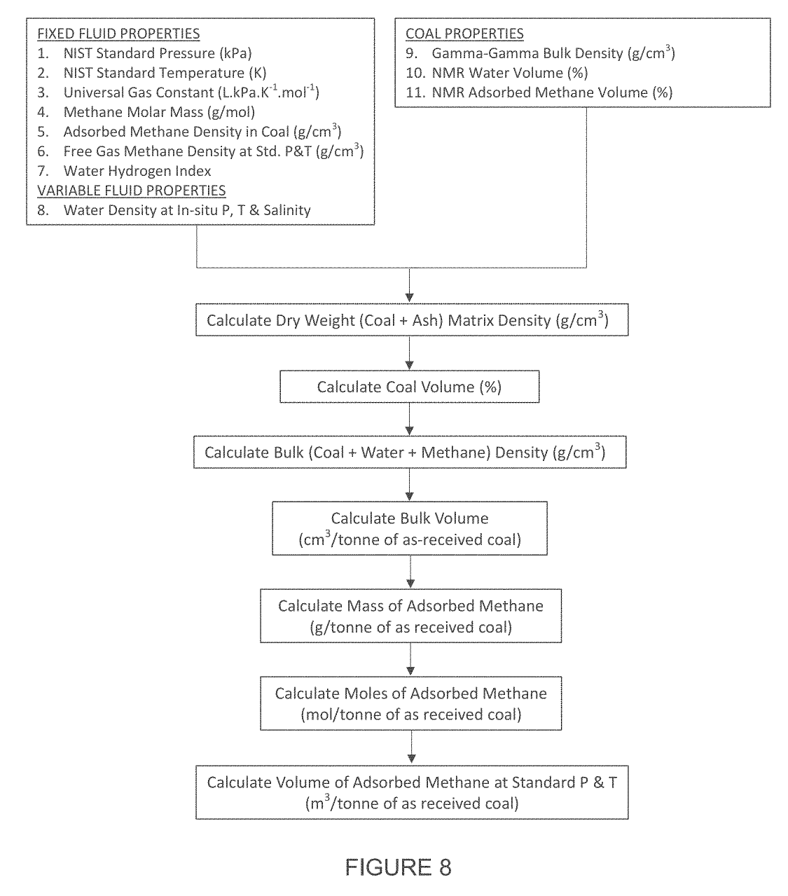

The method of the present invention was applied in a borehole at a survey depth of 200 m in accordance with the routine of FIG. 7. As detailed in FIG. 7, the routine comprised the following steps:
i. Positioning the BMR logging tool to desired location in a wellbore
ii. Polarising spins using a static magnetic field
iii. Setting NMR Pulse Sequence Parameters; e.g. number of diffusion steps, wait time, and number of echoes
iv. Generating pulse sequence on downhole instrumentation that includes a diffusion encoding portion and a relaxation portion
v. Measuring NMR relaxation after the diffusion encoding portion
vi. Phase-cycling the pulse sequence 16 times to obtain a phase-cycled data set
vii. Obtaining phase-cycled data sets for a 11 different δ values
viii. Process series of a phase-cycled data sets in real-time via 2D inversion algorithm to obtain a 2D T₂-StimD map
ix. Ensuring that diffusion resolution is adequate and if required, incorporating additional diffusion encoding steps
x. Calculate volume of adsorbed gas via T₂-StimD map and convert to quantity of gas per unit volume of coal, in accordance with routine of FIG. 8

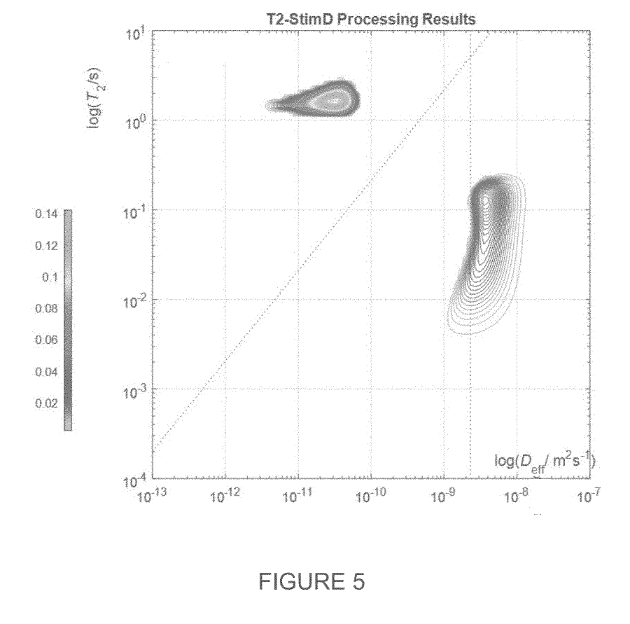

The results of these tests were analysed and two-dimensional T₂-StimD maps were generated. In this test, a 16-part phase cycled encoding step was repeated 11 times for different δ values. Each of the 16 phase encoding steps was then averaged 4 times. The results of these tests were analysed and two-dimensional T₂-StimD maps were generated. FIG. 5 shows the results of this analysis.

The results of the analysis were then used to calculate the volume of the adsorbed gas. The calculation involves the conversion of the adsorbed gas signal (top left of FIG. 5) to m³/tonne of coal. This involves first correcting the adsorbed gas volume for density and hydrogen index. The number of moles of gas (in this example, 99.9% methane) is then calculated at the downhole pressure and temperature. This is then converted to surface conditions, using the routine of FIG. 8.

As detailed in FIG. 8, the routine involves the following steps:
i. Calculate Dry Weight (Coal+Ash) Matrix Density (g/cm³)
ii. Calculate Coal Volume (%)
iii. Calculate Bulk (Coal+Water+Methane) Density (g/cm³)
iv. Calculate Bulk Volume (cm³/tonne of as-received coal)
v. Calculate Mass of Adsorbed Methane (g/tonne of as-received coal)
vi. Calculate Moles of Adsorbed Methane (mol/tonne of as-received coal)
vii. Calculate Volume of Adsorbed Methane at Standard Pressure and Temperature (m³/tonne of as-received coal)
viii. Calculate Moles of Adsorbed Methane (mol/tonne of as-received coal)

For the test of Example 1, the volume of adsorbed gas was calculated to be 16.35 m³ /tonne. For comparative purposes, the sample of Example 1 was brought to the surface and an isotherm desorption analysis was performed. The volume of adsorbed gas calculated by this method was 16.39 m³/tonne, which demonstrates the accuracy of the method of the present invention.

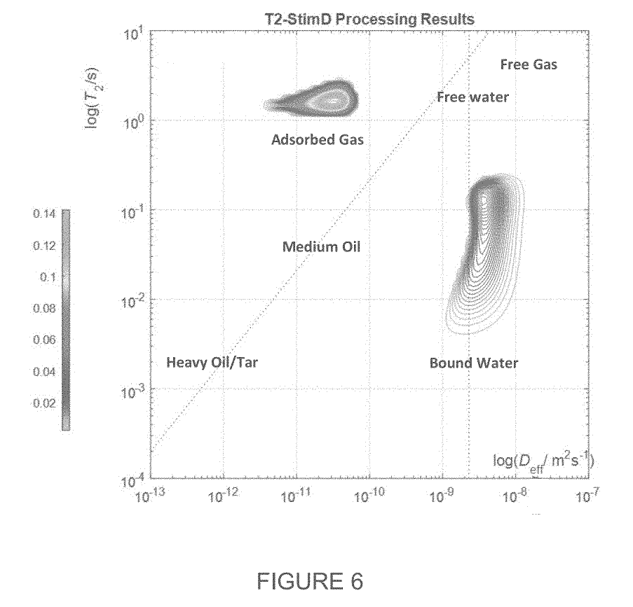

As indicated above, the inventors have identified that the signal at the top left of the T₂-StimD map relates to adsorbed gas within the sample. The method of the present invention may also be used to measure the volume of other components within the sample. FIG. 6 shows the results of Example 1, which has been marked up to indicate the signal areas for other components.

Modifications and variations such as would be apparent to the skilled addressee are considered to fall within the scope of the present invention.

1. A method of determining a multi-dimensional distribution function f(T₂, D) of fluid types in a sample, the method comprising the steps of:
i. applying a sequence of radio frequency (RF) pulses to the sample, each pulse having a predetermined phase, the sequence including: a diffusion encoding portion followed by a series of 180-degree refocusing pulses, wherein the diffusion encoding portion comprises repeating blocks of pulses, where the pulses in each block are separated by an interval time of δ, and the blocks themselves by a time delay (Δ);
ii. measuring a stimulated echo signal from the sample;
iii. repeating steps (i) to (ii) one or more times with constant δ to obtain a phase-cycled data set of stimulated echo signal measurements, wherein for each repetition the phase of at least one of the RF pulses is shifted by a predetermined offset;
iv, repeating steps (i) to (iii) one of more times with different δ values to obtain a series of phase-cycled data sets; and
v. analysing the series of phase-cycled data sets to provide a multi-dimensional distribution function f(T₂, D) of fluid types within the sample.

2. The method according to claim 1, wherein the sample is selected from the group comprising a rock sample, an earth formation, a subsurface each formation, a portion of an earth formation and a portion of a subsurface earth formation.

3. The method according to claim 2, wherein the sample is a portion of earth formation surrounding a borehole.

4. The method according to ns claim 1, wherein the diffusion encoding portion extends for a time, T_{d}, where T_{d} is between 10 ms and 50 ms.

5. The method according to claim 4, wherein T_{d} is between 20 ms and 40 ms.

6. The method according to claim 5, wherein T_{d} is between 25 ms and 35 ms.

7. The method according to claim 6, whereinT_{d} is between 25 ms and 35 ms.

8. The method according to claim 1, wherein an NMR logging tool is used to apply the sequence of RF pulses into the sample.

9. The method according to claim 8, wherein the NMR logging tool is a downhole NMR logging tool.

10. The method according to claim 1, wherein the series of refocusing pulses comprises a series of composite pulses.

11. The method according to claim 1, where Δ is smaller than the longitudinal relaxation time (T₁) associated with the sample.

12. The method according to claim 1, wherein steps (i) to (ii) are repeated for each part of a 16-part phase cycle comprising 16 phase district sequences of radio frequency (RF) pulses.

13. The method according to claim 12, wherein the 16-part phase cycle is repeated one or more times for the same δ value to provide averaged results.

14. The method according to claim 1, wherein phase-cycled data sets are obtained for two or more different δ values.

15. The method according to claim 1, wherein the value of δ is between 0 ms and 30 ms.

16. The method according to claim 1, wherein the value of δ is between 0 ms and 25 ms.

17. The method according to claim 1, wherein the value of δ is between 0 ms and 20 ms.

18. The method according to claim 1, wherein the value of δ is between 0 ms and 15 ms.

19. The method according to claim 1, wherein the series of phase-cycled data sets comprises phase-cycled data sets for eleven uniformly spaced values of δ between 0 ms and 15 ms.

20. The method according to claim 1, wherein the multi-dimensional distribution function f(T₂, D) of the sample is used to determine the volume of fluids in the sample.

21. The method according to claim 20, wherein the multi-dimensional distribution function f(T₂, D) of the sample is used to determine the volume of absorbed gases in the sample.

22. A method of measuring the volume of absorbed gas in a subsurface earth formation, the method comprising the steps of:
provide a multi-dimensional distribution function f(T₂, D) of fluids within the subsurface earth formation using the method of any one of claims 1 to 20; and
ii. using the multi-dimensional distribution function f(T₂, D) of the sample to determine the volume of absorbed gases in the subsurface earth formation.

23. The method according to claim 22, wherein the subsurface earth formation comprises coal.

24. The method according to claim 23, wherein the volume of adsorbed gas in the coal is calculated as a function of m³/tonne of coal.
